(19) United States
(12) Patent Application Publication
(10) Pub. No.: US 2025/0227910 A1
(43) Pub. Date: Jul. 10, 2025

(54) SEMICONDUCTOR STRUCTURE

(71) Applicant: Fujian Jinhua Integrated Circuit Co., Ltd., Quanzhou City (CN)

(72) Inventors: Daochu Wu, Quanzhou City (CN); Chao-Lun Fu, Quanzhou City (CN)

(73) Assignee: Fujian Jinhua Integrated Circuit Co., Ltd., Quanzhou City (CN)

(21) Appl. No.: 18/677,845

(22) Filed: May 29, 2024

(30) Foreign Application Priority Data
Jan. 9, 2024 (CN) 202410032172.0

(51) Int. Cl. H10B 12/00; H01L 21/762

(52) U.S. Cl. CPC H10B 12/0335; H10B 12/315; H10B 12/482; H10B 12/485; H10B 12/50; H01L 21/76224

(57) ABSTRACT

A semiconductor structure includes a substrate having a first region and a second region, an isolation structure in the second region, a plurality of plug structures disposed on the first region and the second region, an insulating structure between the plug structures, and a capacitor structure disposed on the plug structures on the first region. The plug structures include at least an isolated plug structure disposed on the isolation structure in the second region. A portion of the insulating structure on the isolated plug structure has a recess. A filling material layer fills in the recess, and a portion of the filling material layer and a portion of the capacitor structure are made of a same material.

### BACKGROUND OF THE INVENTION

### 1. Field of the Invention

The present invention generally relates to a semiconductor structure, and more particularly, to a semiconductor structure including plug structures disposed on an isolation structure and active areas, respectively.

### 2. Description of the Prior Art

A dynamic random access memory (DRAM) is a kind of volatile memory, which includes a cell region consisting of a plurality of memory cells and a peripheral region consisting of a control circuit. Each memory cell includes a transistor and a capacitor electrically connected to the transistor, and the transistor controls storage or release of charges into or from the capacitor to achieve the purpose of data storage. The control circuit can address each memory cell through word lines (WL) and bit lines (BL), which are distributed all over the cell region and are electrically connected to the memory cells, thereby controlling data access to the memory cells.

In order to obtain enhanced chip density, the structure of the memory cells has been developed towards a three-dimensional configuration, e.g., buried word lines and stacked capacitors. According to the technology of stacked capacitors, capacitors of the memory cells are disposed above the substrate and electrically connected to the transistors in the substrate in a vertical direction through plug structures and connection pad structures, thereby saving the substrate area occupied by the capacitors. In addition, it is easy to increase capacitance by increasing height of an electrode plate of the capacitor. However, there are still some technical problems that need to be further solved. For example, it is necessary to ameliorate structural defects caused by stress in the peripheral region.

### SUMMARY OF THE INVENTION

An object of the present invention is to provide a semiconductor structure including plug structures disposed on both the cell region and the peripheral region, and part of the insulating structure between the plug structures is recessed thereby regulating stress between the cell region and the peripheral region and ameliorating structural defects caused by stress variation. In addition, the end portion of the interconnecting structure that is electrically connected to the bit line contact on the peripheral region is formed in one piece with the bit line contact and at least one of the plug structures adjacent to the bit line contact. By the assistance of the plug structures embedded in the insulating structure, the end portion of the interconnecting structure may be better secured on the peripheral region and prevented from peeling.

According to an embodiment of the present invention, a semiconductor structure includes a substrate having a first region and a second region. The second region of the substrate includes an isolation structure. A plurality of plug structures, an insulating structure, a filling material layer, and a capacitor structure are disposed on the substrate. The plug structures are disposed on the first region and the second region, respectively, and include at least an isolated plug structure disposed on the isolation structure in the second region. The insulating structure is between the plug structures to separate the plug structures from each other. A portion of the insulating structure on the isolated plug structure has a recess, and the filling material layer is in the recess. The capacitor structure is disposed on the plug structures on the first region. A portion of the filling material layer and a portion of the capacitor structure are made of a same material.

According to another embodiment of the present invention, a semiconductor structure includes a substrate including an isolation structure and a plurality of active regions defined by the isolation structure plurality of plug structures disposed on the substrate and first plug structures disposed on active regions and second plug structures disposed on the isolation structure, a dielectric layer between the isolation structure and the second plug structures, a capacitor structure disposed on the first plug structures, an insulating structure between the plug structures, wherein a portion of the insulating structure on the second plug structures comprises a recess, and a filling material layer in the recess. The first plug structures are in direct contact with the active regions. Top surfaces of the second plug structures are lower than top surfaces of the first plug structures. A portion of the filling material layer comprises a same material as the capacitor structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 to FIG. 15 are schematic drawings illustrating intermediates of a semiconductor structure in a manufacturing process according to an embodiment of the present invention, wherein:

FIG. 1 is a plane view of a portion of the semiconductor structure;

FIG. 2 and FIG. 10 are enlarged plane views of a portion of the semiconductor structure shown in FIG. 1;

FIG. 3, FIG. 4, FIG. 5, FIG. 6, FIG. 7, FIG. 9, FIG. 11, FIG. 13 and FIG. 14 are cross-sectional views of the semiconductor structure along line AA′ shown in FIG. 2 or FIG. 10; and

FIG. 8, FIG. 12 and FIG. 15 are cross-sectional views of the semiconductor structure along line BB′ shown in FIG. 10.

### DETAILED DESCRIPTION

For better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

In order to make those of ordinary skilled in the art readily understand the invention and for simplifying the drawings, several drawings in this disclosure only depict a part of the semiconductor structure, and specific elements in the drawings are not drawn to actual scale. In addition, the number and size of each element in the drawings are only for illustration and are not used to limit the scope of the disclosure. It is understood by those of ordinary in the art that the expressions “on”, “above”, “below”, “upper”, “lower”, “over”, “under”, etc. are used for indicating relative positions of the elements, and all the elements can be turned over while still presenting the same structure. Both configurations should belong to the scope disclosed in this specification.

For facilitating descriptions and understanding of the semiconductor structure according to the present invention, spatial reference directions such as a first direction D1, a second direction D2, a third direction D3 and a fourth direction D4 are given in the drawings, wherein the first direction D1, the second direction D2 and the fourth direction D4 are parallel to a surface of the substrate 100, and the first direction D1 and the second direction D2 are perpendicular to each other and both different from the fourth direction D4. The angle between the second direction D2 and the fourth direction D4 may be between 15 degrees and 75 degrees, but it is not limited thereto. The third direction D3 is perpendicular to the surface of the substrate 100. The first direction D1, the second direction D2 and the fourth direction D4 are referred to as horizontal directions. The third direction D3 is referred to as a vertical direction.

In the following description, the terns “formed”, “disposed”, “arranged”, or the like, used to describe a component of the semiconductor structure generally refers to processing a substrate or material layer of the semiconductor structure by a suitable semiconductor manufacturing process to obtain the component, wherein the semiconductor manufacturing process may be, for example, but not limited to, film forming process, etching process, chemical mechanical polishing process, ion implantation process, diffusion process, cleaning process. The film forming process maybe, for example, but not limited to, thermal growth, sputtering, evaporation, physical vapor deposition, chemical vapor deposition, electrochemical deposition, atomic layer deposition, epitaxial growth, or electroplating. The etching process may be, for example, but not limited to, wet etching process or dry etching process.

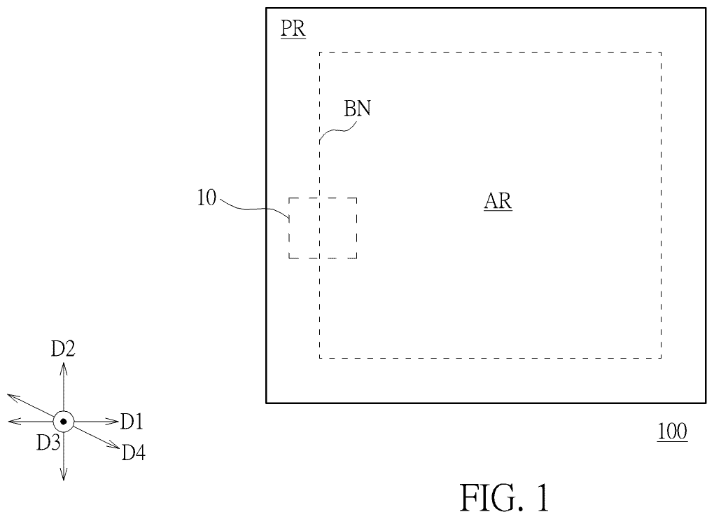

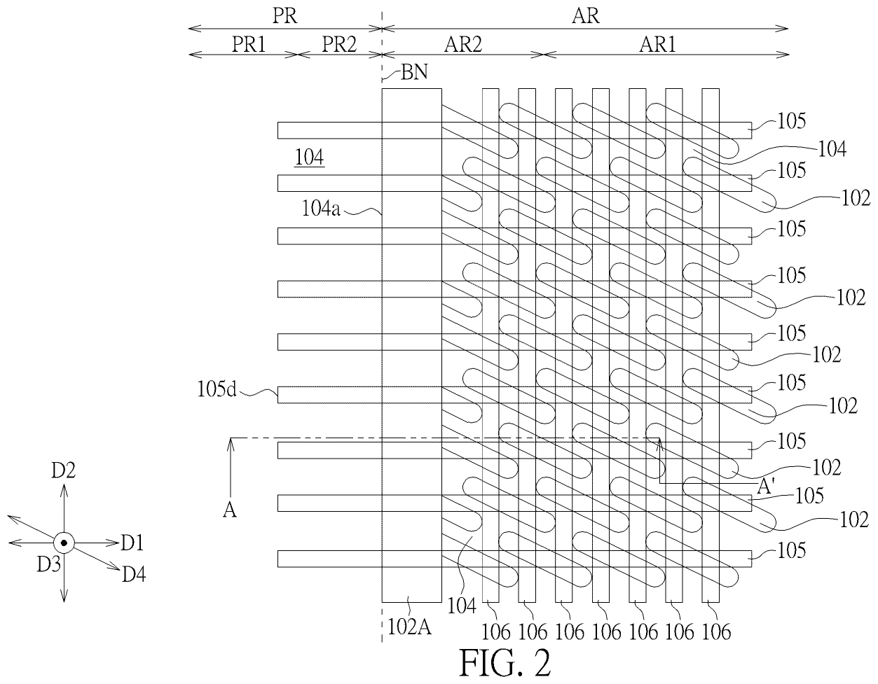

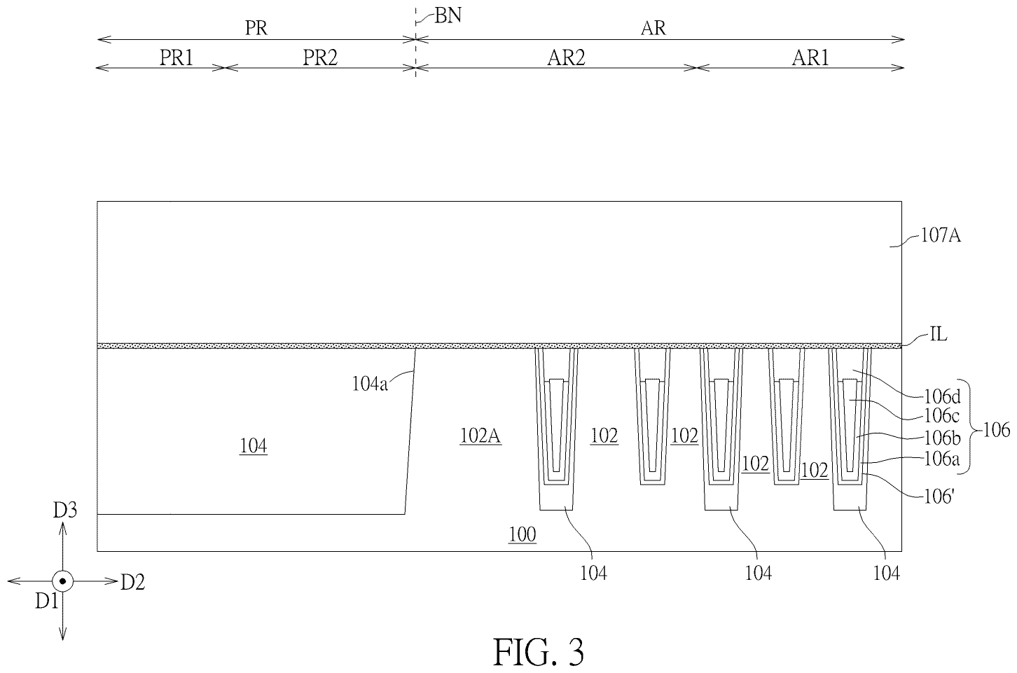

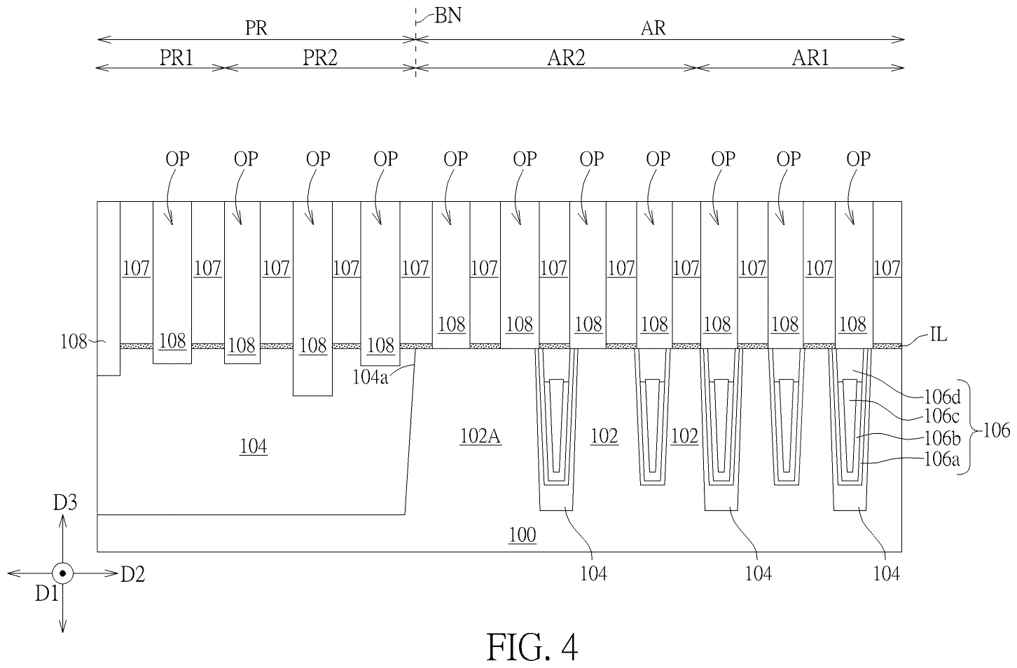

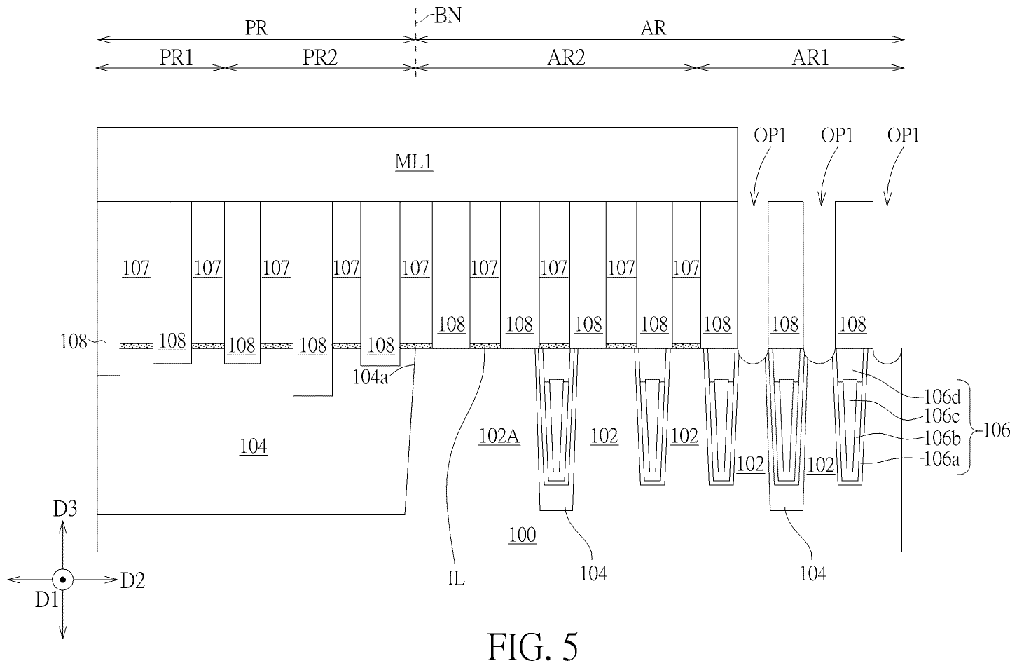

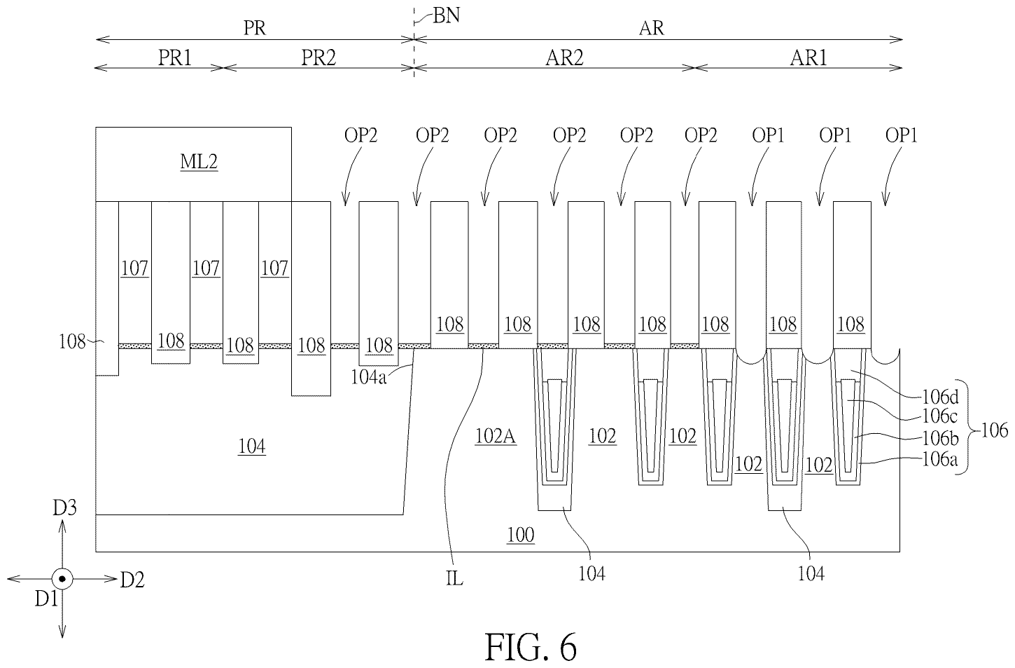

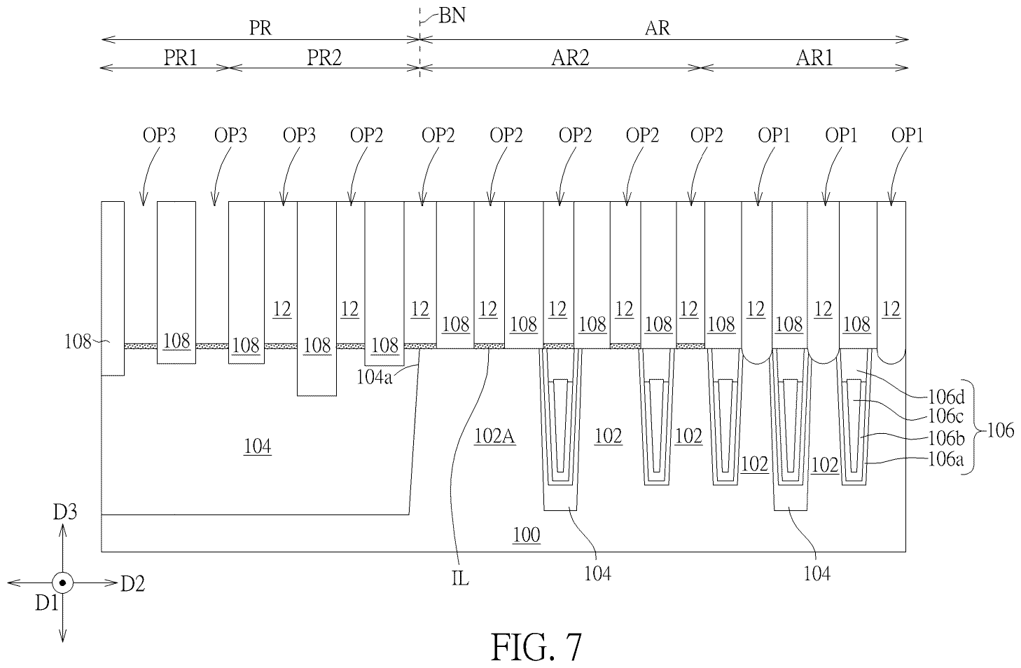

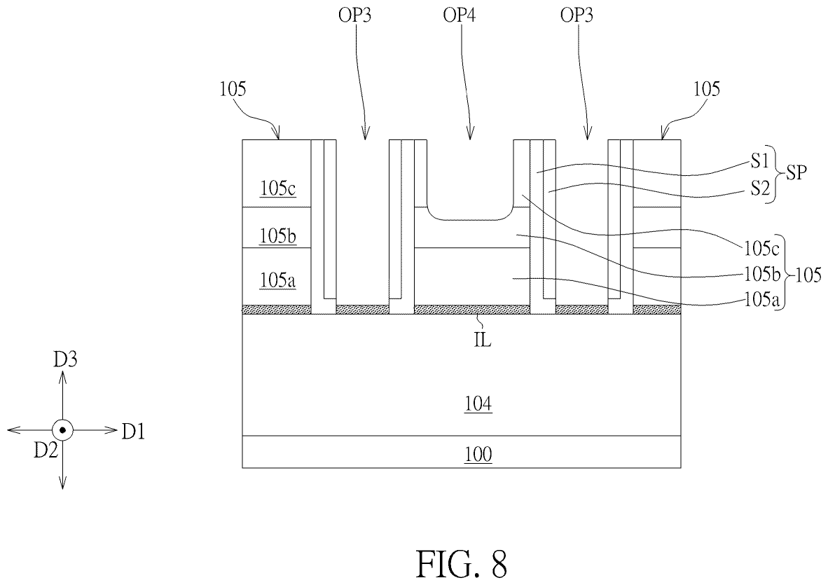

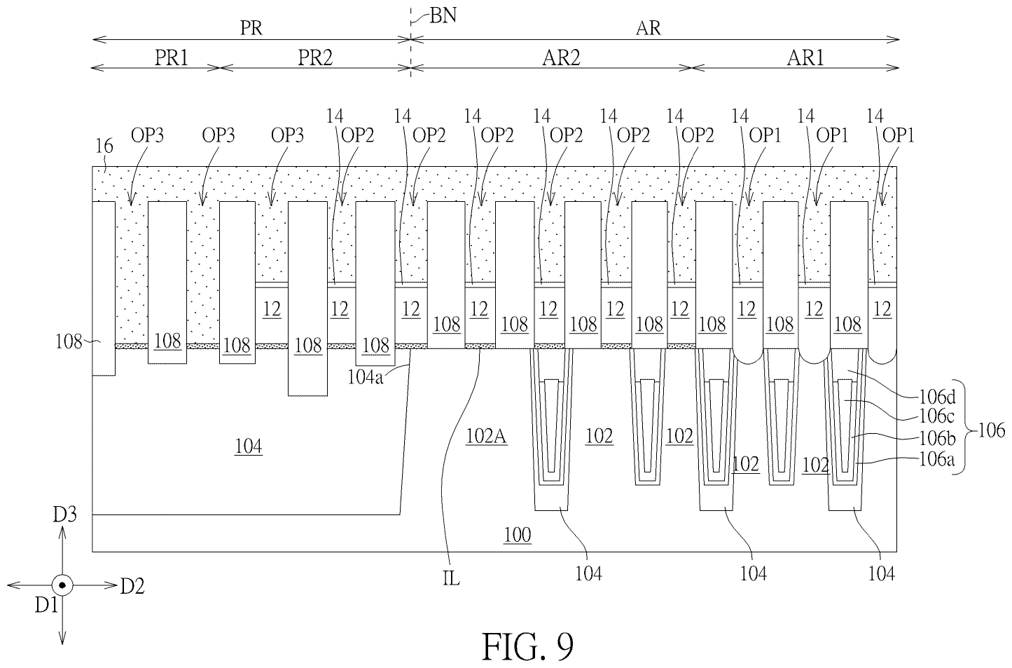

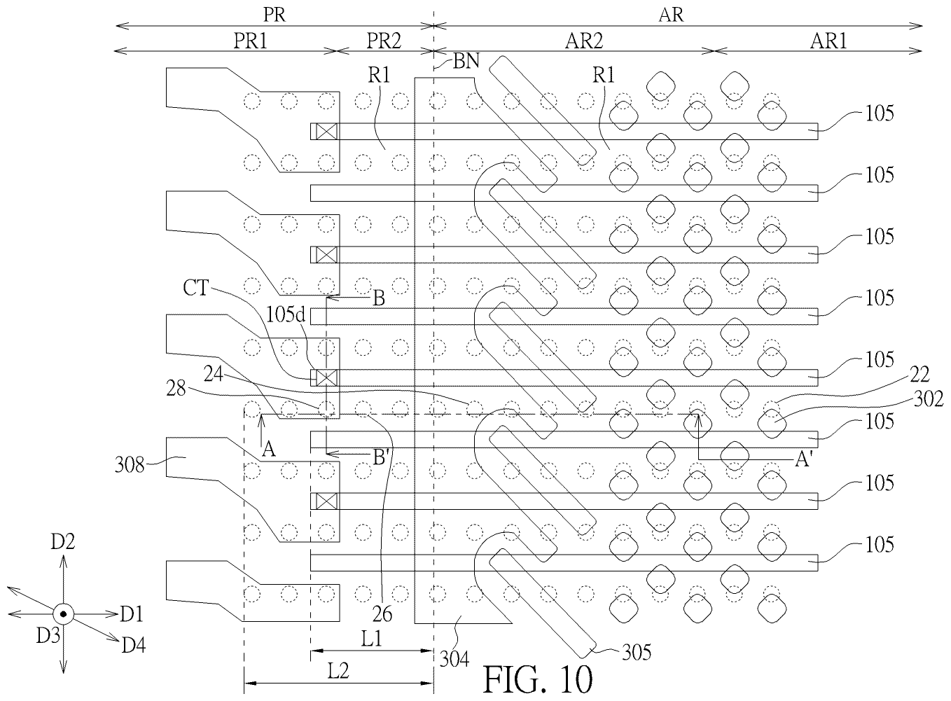

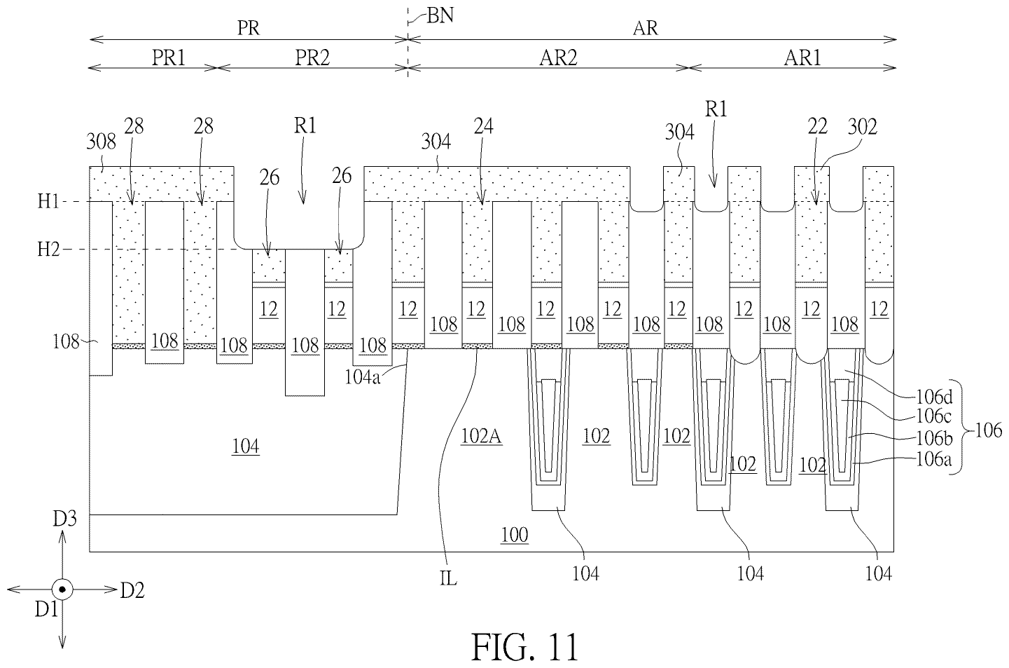

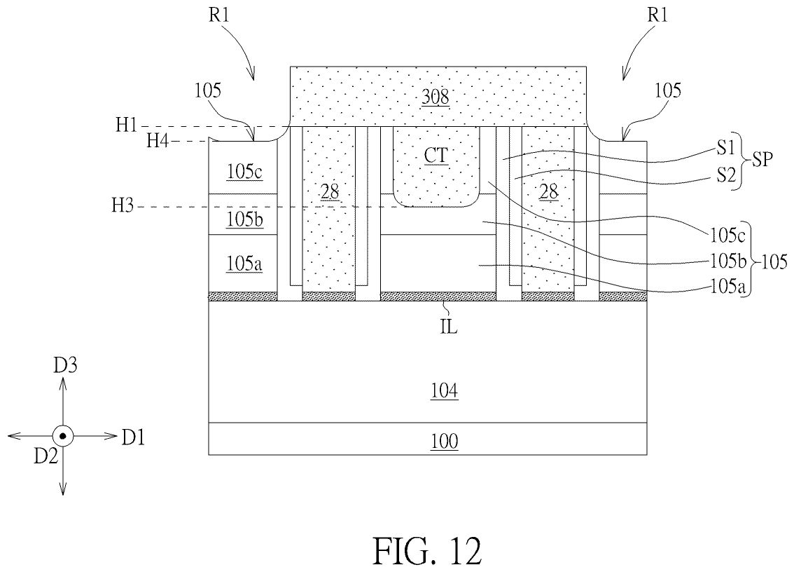

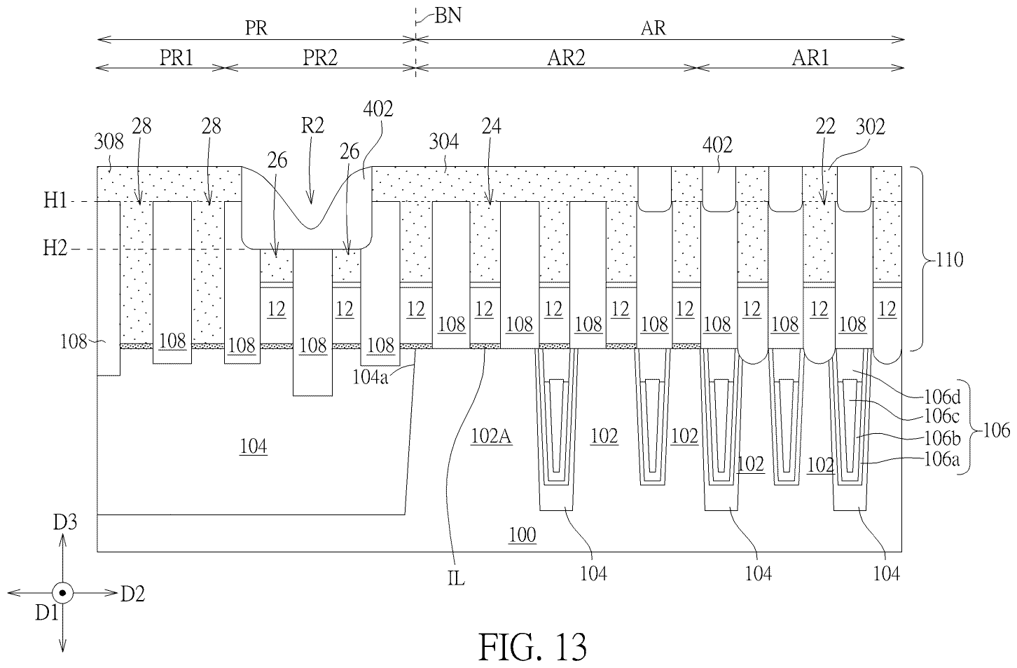

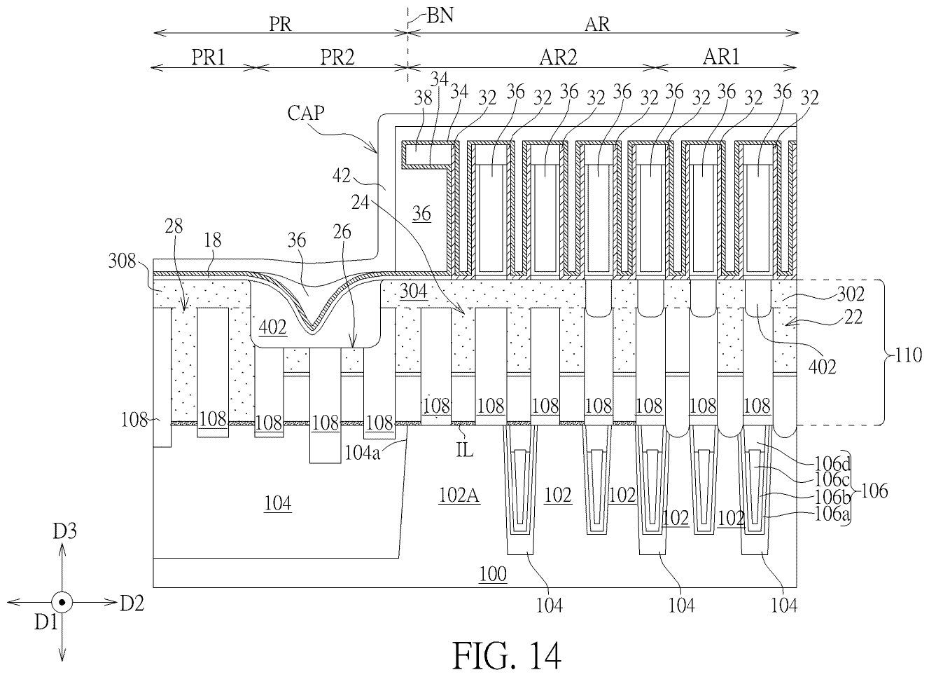

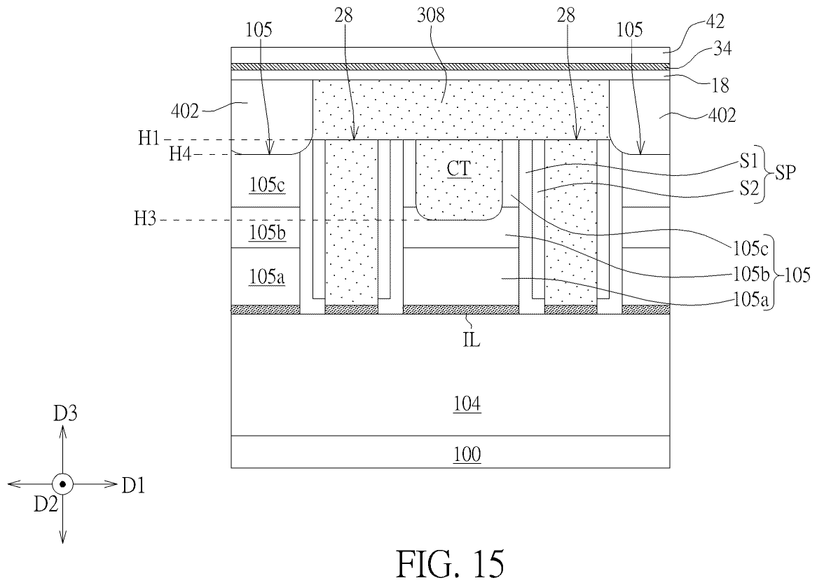

FIG. 1 to FIG. 15 are schematic drawings illustrating intermediates of a semiconductor structure in a manufacturing process according to an embodiment of the present invention. FIG. 1 is a plane view of a portion of the semiconductor structure. FIG. 2 and FIG. 10 are enlarged plane views of a portion of the semiconductor structure shown in FIG. 1. FIG. 3, FIG. 4, FIG. 5, FIG. 6, FIG. 7, FIG. 9, FIG. 11, FIG. 13 and FIG. 14 are cross-sectional views of the semiconductor structure along the line AA′ shown in FIG. 2 or FIG. 10. FIG. 8, FIG. 12 and FIG. 15 are cross-sectional views of the semiconductor structure along the line BB′ shown in FIG. 10. The line AA′ extends between two adjacent bit line structures 105 along the second direction D2. The line BB′ extends along the first direction D1 and crosses the line ends 105d of the bit line structures 105 on the second region PR. The drawings may omit some components of the semiconductor structure for simplicity. For example, in FIG. 2, the spacers SP on the sidewalls of the bit line structures 105 are omitted and not shown. In FIG. 10, the spacers SP and insulating walls 108 are omitted and not shown. The semiconductor structure of the present invention may be used to fabricate dynamic random access memory (DRAM) including stacked capacitors. The semiconductor structure of the present invention may also be used to manufacture other types of semiconductor devices without departing from the scope of the present invention.

Please refer to FIG. 1. A substrate 100 is provided. The substrate 100 may be, for example, but not limited to, a silicon substrate, an epitaxial silicon substrate, a silicon germanium substrate, a silicon carbide substrate, or a silicon-on-insulator (SOI) substrate. The substrate 100 includes a first region AR and a second region PR. The first region AR includes array of memory cells, and may be referred to as a cell region or an array region. The memory cells in the first region AR may be dynamic random access memory cells. The second region PR is next to the first region AR to separate the first region AR from other circuit regions of the substrate 100. The second region may be referred to as a peripheral region. In some embodiments, the second region PR is also the region where word line structures and the bit line structures that control the operation of the memory cells are electrically connected to the peripheral circuits. In some embodiments, the peripheral circuits may include, for example, but not limited to, drivers, buffers, amplifiers, and decoders. It should be noted that the shape and layout of the second region PR and the first region AR shown in FIG. 1 are for illustrative purposes and are not intended to limit the scope of the present invention. The first region AR borders the second region PR along the boundary BN. The first region AR may be divided into a main first region AR1 and a transition first region AR2 that is between the main first region AR1 and the boundary BN. The second region PR may be divided into a main second region PR1 and a transition second region PR2 that is between the main second region PR1 and the boundary BN.

Please refer to FIG. 2. An isolation structure 104 may be formed in the substrate 100 and defines a plurality of active regions 102 in the first region AR and an active region 102A in the first region AR and along the boundary BN. The isolation structure 104 may be shallow trench isolation (STI) structure consisting essentially of a single layer or multiple layers of dielectric material, such as silicon oxide (SiO₂), silicon nitride (SiN), or a combination thereof, but is not limited thereto. The active regions 102 respectively extend lengthwise along the fourth direction D4, and are parallel and staggered to each other to form an array. The end portions of part of the active regions 102 adjacent to the active region 102A are physically connected to the active region 102A. The isolation structure 104 extends in most of the second region PR. The isolation structure 104 in the second region PR has an edge 104a aligned along the boundary BN.

Please refer to FIG. 2 and FIG. 3, showing the cross-sectional view of the word line structures 106 of the semiconductor structure. The semiconductor structure includes a plurality of word line structures 106 disposed in the substrate 100, extending along the second direction D2 and parallel to each other along the first direction. The word line structures 106 cut through the active regions 102 and the isolation structure 104 to divide each of the active regions 102 into two end portions and a middle portion between the end portions. The portions of the word line structures 106 cutting through the active regions 102 are the gates of the transistors of the memory cells. The portions of the word line structures 106 cutting through the isolation structure 104 are the passing gates connected between the gates of the transistors of the memory cells. According to an embodiment of the present invention, the word line structures 106 may be formed by the steps of forming word line trenches 106′ in the substrate 100 and cutting through the active regions 102 and the isolation structure 104, forming a gate dielectric layer 106a along the sidewall and bottom surface of each of the word line trenches 106′, forming a work function metal layer 106b and a conductive layer 106c filling the lower portion of each of the word line trenches 106′, and forming an insulating cap layer 106d filling the upper portion of each of the word line trenches 106′, so that the word line trenches 106′ as shown in FIG. 3 may be obtained. The insulating cap layer 106d and the gate dielectric layer 106a may include dielectric materials, such as silicon oxide (SiO₂), silicon nitride (SiN), silicon oxynitride (SiON), silicon nitrogen carbide (SiCN), nitrogen-doped silicon carbide (NDC), or a combination thereof, but are not limited thereto. In some embodiments, the gate dielectric layer 106a includes a high-k dielectric material, such as hafnium oxide (HfO), hafnium silicate oxide (HfSiO), hafnium silicate nitrogen oxide (HfSiON), aluminium oxide (AlO), lanthanum oxide (LaO), lanthanum aluminate (LaAlO), tantalum oxide (TaO), zirconia (ZrO).), zirconium silicate oxide (ZrSiO), hafnium zirconate (HfZrO), or a combination thereof, but is not limited thereto. In some embodiments, the work function metal layer 106b may include an n-type work function metal, such as titanium-aluminum (TiAl), zirconium-aluminum (ZrAl), tungsten-aluminum (WAl), tantalum-aluminum (TaAl), hafnium-aluminum (HfAl), titanium-aluminum carbide (TiAlC), or a combination thereof, but is not limited thereto. In some embodiments, the work function metal layer 106b may include a p-type work function metal, such as titanium nitride (TiN), tantalum nitride (TaN), tantalum carbide (TaC), or a combination thereof, but is not limited thereto. In some embodiments, the conductive layer 106c may include a metal, such as tungsten (W), copper (Cu), aluminum (Al), titanium (Ti), tantalum (Ta), a compound, an alloy and/or a composite layer of the above-mentioned metals, but it is not limited thereto.

Please refer to FIG. 2 and FIG. 15, showing the cross-sectional view of the bit lines 105 of the semiconductor structure. The semiconductor structure also includes a plurality of bit line structures 105 disposed on the substrate 100, extending along the second direction D2 through the first region AR to the second region PR and parallel to each other. The end portions 105d of the bit line structures 105 are on the main second region PR1. The spacers SP are formed on the sidewalls of the bit line structures 105 to protect the bit line structures 105 and electrically isolate the bit line structures 105 from the plug structures shown in subsequent process. The portions of the bit line structures 105 overlapping and in direct contact with the middle portions of the active regions 102 are the contact regions that are respectively electrically connected to the source regions of the transistors of the memory cells. Each of the spacers SP may include a multilayer structure. As shown in FIG. 15, for example, the spacers SP respectively includes a first dielectric layer S1 and a second dielectric layer S2 disposed on the first dielectric layer S1. The first dielectric layer S1 directly contacts the sidewall of the bit line BL and has a bottom portion showing an L-shaped profile. According to an embodiment of the present invention, the spacers SP may be formed by the steps of forming an insulating layer IL on the substrate 100 and comprehensively covering the active regions 102 and the isolation structure 104 after forming the word line structures 106, forming a patterned mask layer (not shown) on the insulating layer IL and having a plurality of openings directly on the middle portions of the active regions 102, etching and removing the insulating layer IL exposed from the openings to expose the middle portions of the active regions 102, and removing the patterned mask layer. Subsequently, a bit line stack is formed on the substrate 100, which includes, from bottom to top, a semiconductor layer 105a, a metal layer 105b, and a hard mask layer 105c. Following, a patterning process (such as a photolithography-etching process) is performed on the bit line stack material to remove unnecessary portions of the semiconductor layer 105a, the metal layer 105b, and the hard mask layer 105c, thereby obtaining the bit line structures 105. After that, the first dielectric layer S1 and the second dielectric layer S2 are successively formed on the substrate 100 and cover the top surfaces and sidewalls of the bit line structures 105. An anisotropic etching process is carried out to remove the portions of the first dielectric layer S1 and the second dielectric layer S2 on the surface of the substrate 100 and the top surfaces of the bit line structures 105, and the remaining first dielectric layer S1 and second dielectric layer S2 on sidewalls of the bit line structures 105 collectively form the spacers SP.

Please refer to FIG. 3. After forming the bit line structures 105 and the spacers SP, a dielectric layer 107A is formed on the substrate 100, covering the bit line structures 105 and filling the gaps between the bit line structures 105. A polishing process is performed to remove part of the dielectric layer 107A until the top surfaces of the bit line structures 105 (shown in FIG. 2 and FIG. 15, the top surfaces of the bit line structures 105 are the top surfaces of the hard mask layer 105c) are exposed and flush with the top surface of the dielectric layer 107A. According to an embodiment of the present invention, the material of the dielectric layer 107A may include silicon oxide (SiO₂), but is not limited thereto. The dielectric layer 107A is physically separated from and not in direct contact with the active regions 102 and the isolation structure 104 by the insulating layer IL.

Please refer to FIG. 4. Subsequently, the dielectric layer 107A is etched to form a plurality of openings OP, which respectively penetrate through the dielectric layer 107A and are arranged in equal distance from each other between the bit line structures 105 (shown in FIG. 2 and FIG. 15). After that, a dielectric material is formed to fill the openings OP, thereby obtaining the insulating walls 108, which are alternately arranged with the dielectric plugs 107 (the remaining dielectric layer 107A) between the bit line structures.

The materials of the insulating walls 108 and the dielectric plugs 107 are different to provide etching selectivity, allowing the dielectric plugs 107 being selectively etched and removed in a subsequent process. According to an embodiment of the present invention, the material of the dielectric plugs 107 is silicon oxide (SiO₂), and the material of the insulating walls 108 is silicon nitride (SiN). In some embodiments, the bottom portions of the openings OP may penetrate through the insulating layer IL, so that the bottom surfaces of the insulating walls 108 may directly contact the active regions 102 and/or the isolation structure 104. In some embodiments, the pattern density variation in the second region PR may cause loading effect to the etching process for forming the openings OP. As a result, the bottom portions of the openings OP in the second region PR may extend to different depths in the isolation structure 104.

Please refer to FIG. 5. Subsequently, a mask layer ML1 is formed on the substrate 100. The mask layer ML1 covers the main second region PR1, the transition second region PR2, and the transition first region AR2, and exposes the main first region AR2. The mask layer ML1 may be a patterned photoresist layer, but is not limited thereto. Following, a selective etching process, using the mask layer ML1 as an etching mask, is performed to remove the dielectric plugs 107 exposed from the mask layer ML1 and the insulating layer IL under the exposed dielectric plugs 107, thereby obtaining a plurality of openings OP1 on the main first region AR2. The openings OP1 are separated from each other by the insulating walls 108 and expose the active regions 102 of the substrate 100. In some embodiments, the surfaces of the active regions 102 exposed from the openings OP1 may be recessed, and the bottom surfaces of the openings OP1 are lower than the bottom surfaces of the insulating walls 108.

Please refer to FIG. 6. The mask layer ML1 is removed, and another mask layer ML2 is formed on the substrate 100. The mask layer ML2 covers the main second region PR1 and exposes the transition second region PR2, the transition first region AR2, and the main first region AR2. The mask layer ML2 may be a patterned photoresist layer, but is not limited thereto. A selective etching process, using the mask layer ML2 as an etching mask, is performed to remove the dielectric plugs 107 exposed from the mask layer ML2, thereby obtaining a plurality of openings OP2 on the transition second region PR2 and the transition first region AR2. The openings OP2 are separated from each other by the insulating walls 108. As shown in FIG. 6, the insulating layer IL at the bottom portions of the openings OP2 is not removed. The active regions 102 and the isolation structure 104 directly under the openings OP2 are not exposed from the openings OP2. Alternatively, in other embodiments, instead of removing the mask layer ML1 after forming the openings OP1, the mask layer ML1 is trimmed, to be pulled back toward the main second region PR1 until exposing the transition second region PR2 and the transition first region AR2. The trimmed mask layer ML1 is used as the etching mask for forming the openings OP2.

Please refer to FIG. 7 and FIG. 8. The remaining mask layer ML2 (or the mask layer ML1) is removed. A conductive material 12 is formed on the substrate 100 and fills the openings OP1 and the openings OP2. A polishing process or an etching process may be carried out to remove the conductive material 12 outside the openings OP1 and the openings OP2 and expose the top surfaces of the insulating walls 108 and the dielectric plugs 107 on the main second region PR1 (refer to FIG. 6). The material of the conductive material 12 may include poly silicon, but is not limited thereto. In this embodiment, the portions of the conductive material 12 in the openings OP1 are in direct contact with the active region 102 of the substrate 100. The portions of the conductive material 12 in the openings OP2 and the substrate 100 are separated by the insulating layer IL, and are not in direct contact with each other. Subsequently, an opening OP4 through the hard mask layer 105c on the end portion 105d of each of the bit line structures 105 is formed by an etching process. The opening OP4 exposes the metal layer 105b of each of the bit line structures 105. After that, another mask layer (not shown) may be formed to cover regions of the substrate 100 other than the main second region PR1, and an etching process is performed to selectively remove the dielectric plugs 107 on the main second region PR1 exposed from the mask layer, thereby obtaining a plurality of openings OP3 on the main second region PR1. The openings OP3 are separated from each other by the insulating walls 108. As shown in FIG. 7, the openings OP3 are located on the isolation structure 104. The insulating layer IL at the bottom portions of the openings OP3 is not removed, and the isolation structure 104 is not exposed from the openings OP3. In some embodiments, the openings OP3 may be formed before forming the openings OP4.

Please refer to FIG. 9. An etching back process is performed to partially remove the conductive material 12 in the openings OP1 and openings OP2 until the conductive material 12 fills the lower portions of the openings OP1 and openings OP2 and exposes the upper portions of the openings OP1 and openings OP2. Subsequently, another conductive material 16 is formed comprehensively on the first region AR and the second region PR to completely fill the openings OP1, the openings OP2, the openings OP3, and the openings OP4. In some embodiments, the conductive material 16 may include tungsten (W), but is not limited thereto. In some embodiments, the conductive material 12 may fill approximately ⅓ to ½ of the depth of the opening OP1 and the opening OP2, respectively. In some embodiments, a metal silicide 14 may be provided between the conductive material 12 and the conductive material 16. The metal silicide 14 may include a single or multiple layers of, for example, titanium silicide (TiSi), tungsten silicide (WSi), cobalt silicide (CoSi), and/or other metal silicide material layers, but is not limited to.

In an alternative embodiment, the sequence of the steps shown in FIG. 7, FIG. 8, and FIG. 9 may be changed to, for example, etch back the conductive material 12 in the openings OP1 and the openings OP2 in advance of forming the openings OP4 and the openings OP3.

Please refer to FIG. 10, FIG. 11 and FIG. 12. A recess etching process, such as a photolithography etching process, may be performed to etch and pattern the conductive material 16, thereby obtain recesses R1 through the conductive material 16, a plurality of landing pads 302, at least a dam pad 304, a plurality of extending pads 305, a plurality of interconnecting structures 308, a plurality of plugs structures respectively in the openings OP1, OP2, and OP3, and a plurality of bit line contacts CT respectively in the openings OP4. In order to facilitate understanding of the present invention, the plugs structures may be classified according to their locations on the substrate 100 and labeled with different symbols. The plugs structures include plugs structures 22 located on the main first region AR1, the plugs structures 24 located on the transition first region AR2, the plugs structures 26 located on the transition second region PR2, and the plugs structures 28 located on the main second region PR1. In some embodiments, at least one of the plugs structures 24 is located directly on the edge 104a of the isolation structure 104. These plugs structures may provide different functions. The plug structures 22 are formed on the end portions of the active regions 102, and are used as interconnecting plugs to electrically connect the bottom electrodes of the capacitor structure CAP and the drain regions of the transistors of the memory cells. The plug structures 24, the plug structures 26, and the plug structures 28 are dummy plugs used to help control process variation and improve structural robustness. In some embodiments, the farthest distance L2 from the plug structures 28 to the first region AR (that is, the distance between the boundary BN and the one of the plug structures 28 farthest from the boundary BN) is larger than the farthest distance L1 from the line ends 105d of the bit line structures BL to the first region AR. In some embodiments, the recess etching process for forming the recesses R1 may have loading effect caused by the pattern density variation. As a result, the depth of the recess R1 on the second region PR may be larger than the depth of the recess R1 on the first region AR.

The plug structures 22, the plug structures 24 and the plug structures 26 respectively include a lower portion formed by the conductive material 12 and an upper portion formed by the conductive material 16. The lower portions of the plug structures 22 are in direct contact and electrically contacted to the active regions 102. The lower portions of the plug structures 24 are in direct contact with the insulating layer IL and electrically isolated from the active regions 102. The plug structures 26 and plug structures 28 are disposed on the isolation structure 104 and separated from the isolation structure 104, without in direct contact with each other, by the insulating layer IL. The landing pads 302, the dam pad 304, the extending pads 305, and the interconnecting structures 308 are made from the conductive material 16. The landing pads 302 are arranged on the main first region AR1, respectively disposed on the plug structures 22, and integrally formed with the upper portions of the plug structures 22. The dam pad 304 and the extending pads 305 are arranged on the transition first region AR2, wherein part of the dam pad 304 may extend across the boundary BN to the transition second region PR2. The dam pad 304 and the extending pads 305 are disposed on some of the plug structures 24, and integrally formed in one piece with the upper portions of the plug structures 24. The interconnecting structures 308 are arranged on the main second region PR1, respectively disposed on the bit line contacts CT and some of the plug structures 28, and integrally formed in one piece with the upper portions of the plug structures 28. The top surfaces of the plug structures 26 are completely exposed from the recess R1 on the second region PR, lower than the bottom surfaces of the interconnecting structure 308 and the dam pad 304 at two sides of the plug structures 26, and higher than the bottom surfaces of the bit line contacts CT, preferably. As shown in FIG. 11 and FIG. 12, when the surface of the substrate 100 is used as a reference to define the heights of the components, the top surface of the bit lint contact CT (or the bottom surface of the interconnecting structure 308) is at height H1. The top surfaces of the plug structures 26 are at height H2. The bottom surface of the bit lint contact CT is at height H3. The height H2 is between the height H1 and the height H3. In some embodiments, the top surfaces of the bit line structures 105 exposed from the recesses R1 are at height H4, wherein the height H4 is between the height H1 and the height H2.

Please refer to FIG. 13. Subsequently, a dielectric material 402 is formed to fill the recesses R1 between the landing pads 302, the dam pad 304, and the interconnecting structures 308 to ensure electrical isolation between the above structures and planarize the surface topography for implementation of following process. According to an embodiment of the present invention, the dielectric material 402 comprises silicon nitride (SiN), but is not limited thereto.

After completing the above process, a connecting layer 110 of the semiconductor structure of the present invention is obtained. The connecting layer 110 is used to, for example, but not limited to, electrically connect the capacitor structure CAP (refer to FIG. 14) and the transistors of the memory cells formed in the substrate 100. The connecting layer 110 also includes interconnecting structures and contacts to electrically connect the bit line structures and word line structures to the peripheral circuits. The connecting layer 110 includes conductive-material portions such as the plug structures 22, 24, 26, 28, the bit line contacts CT, the landing pads 302, the dam pad 304, the extending pads 305, and the interconnecting structures 308, and dielectric-material portions such as the insulating walls 108 and the dielectric material 402 between the above conductive-material portions. The insulating walls 108 and the dielectric material 402 may be collectively referred to as an insulating structure of the connecting layer 110, wherein the portions of the dielectric material 402 between the landing pads 302 may be referred to as insulating pads. The top surfaces of the plug structures 26 are completely covered by the insulating structure. In other words, the top end, bottom end, and surrounding of each of the plug structures 26 are covered by dielectric materials and electrically isolated. The plug structures 26 may be referred to as isolated plug structures. As shown in FIG. 13, a recess R2 may be formed in the dielectric material 402 filled in the recess R1 above the plug structures 26 when the depth of the recess R1 is increased.

Please refer to FIG. 14 and FIG. 15. Subsequent process is carried out to form a capacitor structure CAP on the connecting layer 110, and a protect layer 42 covering the first region AR and the second region PR and the capacitor structure CAP. As shown in FIG. 14, the capacitor structure CAP includes a plurality of bottom electrodes 32 vertically disposed on the connecting layer 110, a capacitive dielectric layer 34 covering along surfaces of the bottom electrodes 32, and a top electrode layer 36 on the capacitive dielectric layer 34 and capacitively coupled with the bottom electrodes 32 through the capacitive dielectric layers 34. The bottom electrodes 32 and the top electrode layer 36 may include respective conductive materials, such as metal materials. Suitable metal materials may include, for example, but not limited to, tungsten (W), copper (Cu), aluminum (Al), titanium (Ti), tantalum (Ta), a compound, an alloy and/or a composite layer of the above-mentioned metals. In some embodiments, the top electrode layer 36 may include a semiconductor material, such as poly silicon. The capacitive dielectric layer 34 may include a dielectric material, for example, but not limited to, silicon oxide (SiO₂), silicon nitride (SiN), silicon oxynitride (SiON), silicon nitride (SiCN), nitrogen-doped silicon carbide (NDC) or a combination of the above materials. In some embodiments, the capacitive dielectric layers 34 may include a high-k metal oxide dielectric material such as Hafnium oxide (HfO), hafnium oxide silicate (HfSiO), hafnium oxynitride silicate (HfSiON), aluminum oxide (AlO), lanthanum oxide (LaO), lanthanum aluminate (LaAlO), tantalum oxide (TaO), zirconium oxide (ZrO), zirconium oxide silicate (ZrSiO), or hafnium zirconate (HfZrO), etc., but it is not limited thereto. The capacitor structure CAP further includes at least one support layer 38 horizontally extending between the bottom electrodes 32 of the capacitor structure CAP and being in direct contact with and supporting each of the bottom electrodes 32. In some embodiments, an etch stop layer 18 may be disposed between the capacitor structure CAP and the connecting layer 110, wherein bottoms of some of the bottom electrodes 32 penetrate through the etch stop layer 18 and are in direct contact with the landing pads 302 of the connecting layer 110, respectively. In some embodiments, some of the bottom electrodes 32 are disposed on the dam pad 304, having bottoms thereof penetrating through the etch stop layer 18 on the dam pad 304 and in direct contact with the dam pad 304. The bottom electrodes 32 on the dam pad 304 may increase physical support to the edge portion of the capacitor structure CAP, so that defects caused by deformation or collapse may be reduced. The support layer 38 and the etch stop layer 18 may include respective dielectric materials, for example, but not limited to, silicon oxide (SiO₂), silicon nitride (SiN), silicon oxynitride (SiON), silicon nitride (SiCN), nitrogen-doped silicon carbide (NDC) or a combination of the above materials.

Part of the etch stop layer 18 and part of the materials of the capacitor structure CAP may fill into the recess R2 and become a filling material layer located in the recess R2. As shown in FIG. 14, the filling material layer is a multilayer structure, including a lower layer made from the etch stop layer 18, a middle layer made from the capacitive dielectric layer 34, and an upper layer made from the top electrode layer 36, wherein the upper layer is completely located in the recess R2, and the middle layer and the lower layer are respectively continuously connected with the capacitive dielectric layer 34 and the etch stop layer 18 outside the recess R2 to form a V-shaped or U-shaped cross-sectional profile. In other embodiments, the filling material layer may include a lower layer made from the etch stop layer 18, a middle layer made from the capacitive dielectric layer 34, and an upper layer made from part of the protect layer 42 filling into the recess R2, and without any portion made from the top electrode layer 36.

After completing the above process, the semiconductor structure according to the present invention is obtained. The semiconductor structure includes a substrate 100 including a first region AR and a second region PR. An isolation structure 104 formed in the substrate 100 to define a plurality of active regions 102 in the substrate 100. A plurality of plug structures are disposed on the substrate 100 and separated from each other by an insulating structure. The plug structures include a plurality of plug structures 22 and plug structures 24 disposed on the first region AR, and plug structures 26 and plug structures 28 disposed on the second region PR. The plug structures 22 are respectively disposed on the active regions 102 and electrically connected to the active regions 102, and may be referred to as first plug structures. The plug structures 26 are disposed on the isolation structure 104 in the second region PR, wherein the top surfaces of the plug structures 26 are completely covered by the insulating structure and lower than the top surfaces of the plug structures 22. The plug structures 26 may be referred to as second plug structures or isolated plug structures. The insulating structure includes insulating walls 108 and a dielectric material 402. The portion of the insulating structure above the plug structures 26 includes a recess R2, and a filling material layer is disposed in the recess R2. A capacitor structure CAP is disposed on the plug structures 22 and the plug structures 24. A portion of the filling material layer in the recess R2 and a portion of the capacitor structure CAP, such as the capacitive dielectric layer 34 or the top electrode layer 36, are made of a same material.

In summary, the semiconductor structure provided according to the present invention includes plug structures made of conductive materials disposed on the first region (or the cell region) and the second region (or the peripheral region) and a recess formed in the insulating structure on the second region and filled by the materials formed in subsequent process, so that the technical effect of adjusting the stress between the first region and the second region may be achieved, and structural defects caused by stress variation due to significant differences in pattern density and material composition between the first region and the second region can be reduced. In addition, the end portion of the interconnecting structure on the second region is formed in one piece with the bit line contact and at least one of the plug structures adjacent to the bit line contact. By the assistance of the plug structures embedded in the insulating structure, the end portion of the interconnecting structure may be better secured on the second region and prevented from peeling . . .

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a substrate comprising a first region and a second region, the second region comprising an isolation structure;
a plurality of plug structures disposed on the first region and the second region and comprising at least an isolated plug structure disposed on the isolation structure in the second region;
an insulating structure between plug structures, wherein a portion of the insulating structure on the isolated plug structure comprises a recess;
a filling material layer in the recess; and
a capacitor structure disposed on the plug structures on the first region, wherein a portion of the filling material layer and a portion of the capacitor structure are made of a same material.

2. The semiconductor structure according to claim 1, wherein at least one of the plug structures is disposed on an edge of the isolation structure.

3. The semiconductor structure according to claim 1, wherein bottom portions of the insulating structure on the isolation structure are at different depths in the isolation structure.

4. The semiconductor structure according to claim 1, further comprising:
a bit line disposed on the substrate and extending from the first region to the second region; and
a bit line contact disposed on the second region and in direct contact with a line end of the bit line.

5. The semiconductor structure according to claim 4, wherein a top surface of the bit line contact is at a first height, a top surface of the isolated plug structure is at a second height, a bottom surface of the bit line contact is at a third height, wherein the second height is between the first height and the third height.

6. The semiconductor structure according to claim 4, wherein a farthest distance from the plug structures to the first region is larger than a distance from the line end of the bit line to the first region.

7. The semiconductor structure according to claim 1, wherein the capacitive structure comprises:
a plurality of bottom electrodes;
a capacitive dielectric layer covering along surfaces of the bottom electrodes; and
a top electrode layer disposed on the capacitive dielectric layer.

8. The semiconductor structure according to claim 7, wherein a portion of the filling material layer comprises a same material as the capacitive dielectric layer.

9. The semiconductor structure according to claim 7, wherein a portion of the filling material layer comprises a same material as the top electrode layer.

10. The semiconductor structure according to claim 7, wherein the filling material layer has a multilayer structure.

11. The semiconductor structure according to claim 1, wherein a bottom surface of the recess is higher than a top surface of the isolated plug structure.

12. The semiconductor structure according to claim 1, further comprising a plurality of landing pads on the plug structures on the first region, respectively, wherein the insulating structure comprises insulating walls between the plug structures and insulating pads between the landing pads, wherein a lowest portion of the filling material layer is lower than bottom surfaces of the insulating pads.

13. A semiconductor structure, comprising:
a substrate, comprising an isolation structure and a plurality of active regions defined by the isolation structure;
a plurality of plug structures disposed on the substrate, comprising first plug structures disposed on active regions and second plug structures disposed on the isolation structure, wherein the first plug structures are in direct contact with the active regions, and top surfaces of the second plug structures are lower than top surfaces of the first plug structures;
a dielectric layer between the isolation structure and the second plug structures;
a capacitor structure disposed on the first plug structures;
an insulating structure between the plug structures, wherein a portion of the insulating structure on the second plug structures comprises a recess; and
a filling material layer disposed in the recess, wherein a portion of the filling material layer comprises a same material as the capacitor structure.

14. The semiconductor structure according to claim 13, wherein the capacitor structure comprises:
a plurality of bottom electrodes;
a capacitive dielectric layer covering along surfaces of the bottom electrodes; and
a top electrode layer disposed on the capacitive dielectric layer.

15. The semiconductor structure according to claim 14, wherein a portion of the filling material layer comprises a same material as the capacitive dielectric layer.

16. The semiconductor structure according to claim 14, wherein a portion of the filling material layer comprises a same material as the top electrode layer.

17. The semiconductor structure according to claim 14, wherein the filling material layer has a multilayer structure.

18. The semiconductor structure according to claim 13, wherein a bottom surface of the recess is higher than a top surface of the second plug structures.

19. The semiconductor structure according to claim 13, further comprising a plurality of landing pads on the first plug structures, respectively, wherein the insulating structure comprises insulating walls between the first plug structures and insulating pads between the landing pads, wherein a lowest portion of the filling material layer is lower than bottom surfaces of the insulating pads.
